(19) United States
(12) Patent Application Publication
(10) Pub. No.: US 2023/0177107 A1
(43) Pub. Date: Jun. 8, 2023

(54) ARRANGEMENT AND METHOD FOR PERFORMING A VECTOR-MATRIX MULTIPLICATION BY MEANS OF CAPACITIVE OR RESISTIVE SYNAPTIC COMPONENTS

(71) Applicant: SEMRON GMBH, Dresden (DE)

(72) Inventors: Kai-Uwe DEMASIUS, Dresden (DE); Aron KIRSCHEN, Dresden (DE)

(73) Assignee: SEMRON GMBH, Dresden (DE)

(21) Appl. No.: 17/997,394

(22) PCT Filed: Apr. 29, 2021
(86) PCT No.: PCT/EP2021/061334

§ 371 Date: Oct. 28, 2022

(30) Foreign Application Priority Data
Apr. 29, 2020 (EP) 20172081.0
Jul. 24, 2020 (EP) 20187663.8

(51) Int. Cl. G06F 17/16; G06F 1/08

(52) U.S. Cl. CPC G06F 17/16; G06F 1/08

(57) ABSTRACT

A method and arrangement for performing a vector-matrix multiplication by synaptic components includes—a matrix arrangement of components in a differential arrangement, which are periodically charged and discharged; and—a clock generator, which connects the bit lines alternately to a charge integration amplifier or to a ground by means of a changeover switch. The method and arrangement addresses the problem of implementing a switched capacitor arrangement which uses capacitive, resistive or capacitive-resistive components and which uses different variations of an alternating voltage signal as an input variable. The word lines of the matrix are connected to one or more oscillators and the clock generator either reacts to rising or falling voltages of the oscillators or reacts to a positive or negative value range of the voltage of the oscillators.

The present invention relates to an arrangement for performing a vector-matrix multiplication by means of synaptic components, consisting of a matrix arrangement of capacitive or resistive or capacitive-resistive synaptic components in a differential arrangement, which are periodically charged and discharged, and a clock generator which alternately connects the bit lines to a charge integration amplifier or to ground via a changeover switch.

The invention likewise relates to a method for controlling the arrangement in order to achieve the vector-matrix multiplication.

A synaptic component is understood as meaning a component for weighted multiplication in artificial neural networks.

Vector-matrix multiplications are frequently used in artificial neural networks and are extremely computationally intensive when implemented on conventional digital computer architectures.

Artificial neural networks have become increasingly important in recent years in image and object recognition and data processing and will have an important relevance in future in the implementation of artificial intelligence.

In artificial neural networks, the outputs of artificial neurons are connected to inputs of further artificial neurons via synaptic links. The synaptic links effect a weighted multiplication by the output signals from the artificial pre-neurons. A matrix arrangement has been found to be a favorable arrangement of artificial synaptic components in recent years since each pre-neuron is connected, via the word lines, to each post-neuron via the bit lines and a high connection density can therefore be achieved (Tsai et al.: Recent progress in analog memory-based accelerators for deep learning). The individual multiplications are summed on the bit lines and a multiplication and accumulation operation is therefore achieved. The neurons are often non-linear functions (for example sigmoid or ReLU) or may be a temporal integration with a threshold value.

Resistive components, for example memristors (US20180019011A1), phase change memory or floating gate transistors, are often used for the physical implementation. It is likewise conceivable to use memcapacitive components (US20120014170A1, WO2011025495A1, DE102014105639B3, U.S. Pat. No. 5,524,092A1, US2019303744A1, Ventra et al.: Circuit elements with memory—memristors, memcapacitors, and meminductors, Proceedings of the IEEE) which have the advantage of a lower static power consumption and dynamic losses can be largely eliminated with adiabatic charging.

It is likewise already known that the input signals can be coded differently in order to achieve a weighted multiplication: as a variation of the input voltage or as a variation of a temporal length of an input pulse (Tsai et al.: Recent progress in analog memory-based accelerators for deep learning).

US20120014170A1 has already proposed a matrix arrangement of capacitive synaptic components and likewise a writing and reading method. In this case, reading is carried out using voltage pulses.

WO2016068886A1 proposed the use of an alternating signal during reading and the fact that capacitive components have advantages over resistive synaptic components when using dynamic variables. The output current dependence on the frequency of the input variable was also explained.

U.S. Pat. No. 5,343,555 proposed a switched capacitor arrangement for reading exhibitory and inhibitory synapses. The synapses are still not memcapacitive components directly, but rather use is made of charges of conventional capacitances and the storage content of floating gate transistors. The synaptic component therefore still occupies considerably more area. However, the invention is already based on the fact that a charge integration amplifier is used and the synaptic capacitances are charged and discharged periodically by means of two clock pulses which do not overlap and the charge is transferred to the charge integration amplifier. The different phases of the exhibitory and inhibitory synapses are likewise described. However, the invention still uses a temporal pulse width change, rather than an alternating signal, as the input signal. Accordingly, no phase change is used in the input signal or the weights and accordingly no four-quadrant multiplication is performed, but is often necessary in artificial neural networks. However, since the patent is closest to the invention described here, it is used here as the prior art.

The invention was therefore based on the object of implementing a switched capacitor arrangement which uses capacitive, resistive or capacitive-resistive components and uses different variations of an AC voltage signal as an input variable. This scheme is intended to enable a four-quadrant multiplication, and the oscillator for the AC voltage signal and the frequency should be designed such that a minimum energy consumption becomes possible.

According to the invention, this object is achieved, in terms of the arrangement, by means of an arrangement having the features of claim 1. Embodiments of this are described in dependent claims 2 to 10.

The object according to the invention is also achieved by means of a method as claimed in claims 11 to 13. Configurations of the method are described in dependent claims 14 to 19.

An arrangement of the type mentioned at the outset is designed, according to the invention, by virtue of the fact that the word lines of the matrix are connected to one or more oscillators and the clock generator reacts either to rising or to falling voltages of the oscillators or reacts to a positive or negative value range of the voltage of the oscillators.

In one embodiment for capacitive synaptic components, the clock generator reacts to rising or falling edges, during which the capacitances are charged or discharged, that is to say the current flow, and therefore the charge inflow and outflow, is dependent on the derivative of the voltage change in the case of capacitive synaptic components:

$$I = \frac{dU}{dt} \cdot C$$

Since this charge inflow and outflow is ultimately integrated by the charge integration amplifiers on the bit lines, the rising and falling voltage of the oscillator is decisive in the case of capacitive synaptic components.

In a further embodiment, it is likewise conceivable, in the case of capacitive synaptic components, in particular positively defined capacitances and negatively defined capacitances, for the bit line to be connected to ground via a fixed capacitance and for the clock generator to be designed to react to the positive and negative value range of the voltage of the oscillator. The voltage drop across the capacitance is phase-shifted through 90° with respect to the charging or discharging current, which is why the clock generator does not have to react with a 90° phase shift this time, as in the previous exemplary embodiment. The capacitance mentioned may also be the parasitic capacitance of the bit line. In that case, the charge integration amplifier must react to the voltage drop across the fixed capacitance.

In one embodiment, in the case of resistive synaptic components, in particular positively defined resistances and negatively defined resistances, the clock generator is designed to react to the positive and negative value range of the voltage of the oscillator. In this case, the current flow is not dependent on the derivative of the voltage, but rather is proportional to it. Accordingly, the clock generator again does not need a 90° phase shift.

In one embodiment, the charge integration amplifier consists of a current mirror, in a further embodiment consists of a gate circuit, and in a further embodiment the charge is directly integrated onto a capacitor. In one embodiment, it is also possible to use a Miller capacitance in order to achieve a low input-side impedance.

A low input impedance is decisive for the charge integration amplifier so that the charges on the bit line are mainly received by the charge integration amplifier and are not lost in parasitic capacitances or resistances.

This is enabled with the four embodiments described. However, parasitic capacitances can also be used, as in the case of claim 3, for example.

In a further embodiment, the oscillator may contain an energy store which may consist of an inductance in a further embodiment. This makes it possible to effectively recover stored charges in the matrix arrangement and to largely eliminate dynamic losses with adiabatic charging. This enables extremely high energy efficiency when calculating artificial neural networks.

The method-related achievement of the object according to the invention of performing a vector-matrix multiplication in an arrangement according to the invention comprises the following steps defined on a case-by-case basis:

In the case of a matrix of capacitive synaptic components and a clock generator which reacts to the positive or negative gradient:
the AC voltages have a fixed phase relationship,
in the case of an alternating connection between ground and the input of the charge integration amplifier, the bit line of the positively provided capacitances is connected to the input of a charge integration amplifier when there is a positive gradient in the positively defined AC voltage signal of the word line, and is otherwise connected to ground, which causes a positive current flow into the charge integration amplifier and results in a positive voltage drop,
the bit line of the capacitances provided as negative is connected to the input of the charge integration amplifier when there is a negative gradient in the positively defined AC voltage signal of the word line, and is otherwise connected to ground, which causes a negative current flow into the charge integration amplifier and results in a negative voltage drop.

This ensures that the AC signal on the bit line is effectively rectified and integrated.

In the case of a differential charge integration amplifier, both phases may also be rectified and used, as a result of which the effective gain is doubled:
in the case of an alternating connection between the inverting input and the non-inverting input of the charge integration amplifier
the positively provided capacitances are connected to the non-inverting input of a charge integration amplifier when there is a positive gradient in the positively defined AC voltage signal of the word line, and are otherwise connected to the inverting input, and
the negatively provided capacitances are connected to the non-inverting input of a charge integration amplifier when there is a negative gradient in the positively defined AC voltage signal of the word line, and are otherwise connected to the inverting input.

In the case of a negatively defined AC voltage signal, the positive and negative gradients are swapped in time on the word line, with the result that the positive and negative currents are swapped.

This makes it possible to achieve a four-quadrant multiplication.

In another exemplary embodiment for resistive components or capacitive components with an additional capacitance on the bit line, either the in-phase current or the in-phase voltage drop across the additional capacitance is effectively rectified with respect to the applied periodic AC voltage signal. In this case, the clock generator reacts to the positive and negative value range of the AC voltage signal.

In a further exemplary embodiment for mixed capacitive-resistive synaptic components, the time for a connection between ground and the input of the charge integration amplifier is arbitrarily selected, but has a length of exactly half a period duration. The same applies to the case of a differential amplifier with a non-inverting input and an inverting input. Since a mixed capacitive-resistive synaptic component no longer has any fixed phase relationship, the time for the clock signal reaction cannot be exactly defined. Depending on the phase shift, the charge accumulated in the charge integration amplifier is different and the phase/times of the AC voltage signal on the word line can therefore be arbitrarily selected. The times/phase should preferably be selected to correspond either to the purely capacitive case or to the purely resistive case.

In one embodiment, the AC voltage signals are harmonic, and positive and negative AC voltage signals are phase-shifted through 180°. Harmonic AC voltage signals have the advantage that no harmonics occur and the shielding layer can shield the signals well and fewer charges are lost in parasitic capacitances. In addition, resistive losses in the case of capacitive synaptic components are lower, with the result that more energy can be recovered using the previously mentioned adiabatic charging.

In one embodiment, the input variable can be represented either as a variable number of periods, or as a phase shift, or as an amplitude change, or as a frequency change of the AC voltage signal, or as a changed DC component of the AC voltage signal, or as a combination of the changes mentioned above. Since the charge integration amplifier integrates the charge or discharge over a plurality of periods, the number of periods in the AC voltage signal can be used to represent the input variable. Only two phases have previously been used for positive and negative input signals (phase shift of 180°). It is also possible to use any phase shifts in between to represent the input signal: in this case, the charge integration amplifier integrates not only the falling or rising edges of the AC voltage signal, but also over both phases or over a shorter period in one phase. This enables an analog value representation of the input signal. An amplitude change of the AC voltage signal is likewise conceivable since the charge and discharge are lower or higher as a result. In the case of a fixed integration period, a frequency change of the AC voltage signal results in more or fewer charges and discharges and therefore in a smaller or larger output signal from the charge integration amplifier. In the case of non-linear components, a changed DC component of the AC voltage signal may result in a changed operating point and therefore in a stronger or weaker output signal. It is likewise conceivable to combine the five possible ways of setting the input value which have been mentioned.

In a further exemplary embodiment, the weights in a mixed capacitive-resistive matrix can also be set by means of the complex and real parts for a constant impedance and can cause a phase shift of the AC voltage signal. The usual way of changing the weight value is to vary the absolute impedance, but mixed capacitive-resistive weight values can also be changed in terms of the phase relationship since the integration scheme explained above is phase-sensitive. This opens up a further possible way of changing the weight value, in addition to the absolute impedance value.

In one embodiment, a plurality of AC voltage signals can be applied to the word lines in a parallel manner and differ in terms of the frequency, and a plurality of charge integration amplifiers which are each responsible for the individual frequency bands are respectively situated on the bit lines. In convolutional neural networks in particular, the same weight matrix is used for a plurality of input pixel fields. This is normally a serial process in which the input pixel fields are created in succession. The use of a plurality of bands which each an input pixel field can parallelize this process. The charge integration amplifiers must then be able to distinguish the frequency bands.

In a further embodiment, a bandpass filter, for example in the form of a lock-in amplifier, is used to select the bands.

In a final method-related embodiment, the frequency of the applied AC voltage signal is minimized in the case of capacitive synaptic components to such an extent that resistive losses in the supply lines of the matrix arrangement and in the capacitive synaptic component itself are smaller by at least one order of magnitude than the capacitive energy supply. This ensures that a large part of the supplied dynamic energy can be recovered using the adiabatic approach.

The invention shall be explained in more detail below on the basis of a plurality of exemplary embodiments. In the associated drawings:

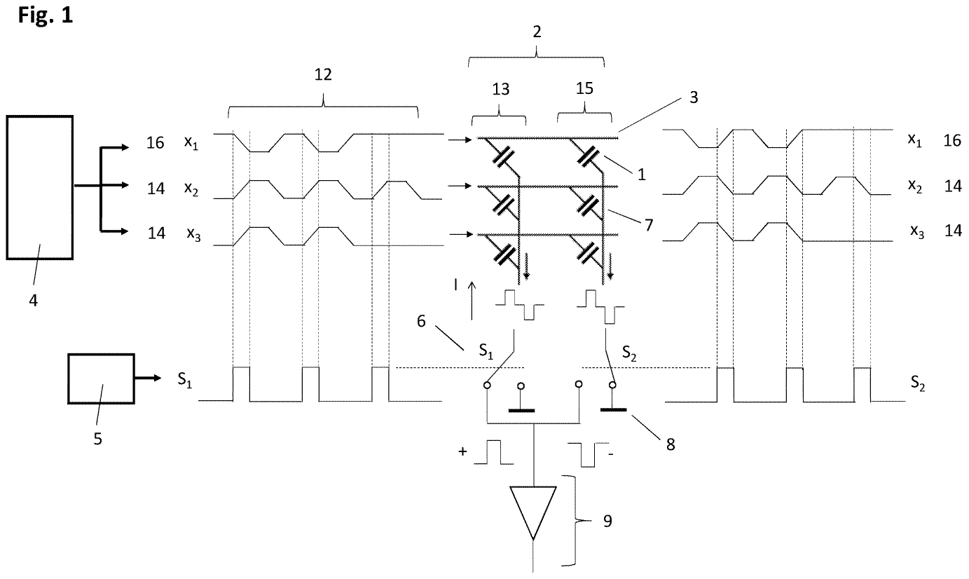

FIG. 1: shows a circuit design with an oscillator, a clock generator, a changeover switch, a charge integration amplifier and a capacitive matrix as well as the alternating signals applied to the word lines

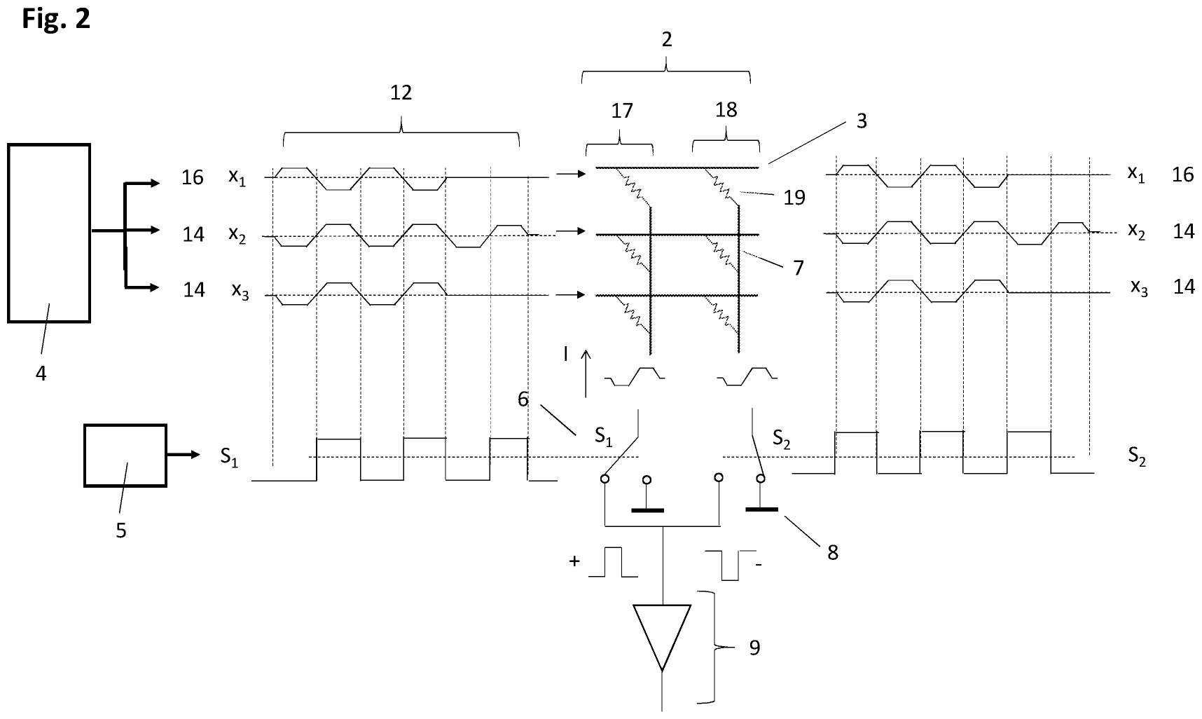

FIG. 2: shows a circuit design and alternating signal relationships for a resistive matrix

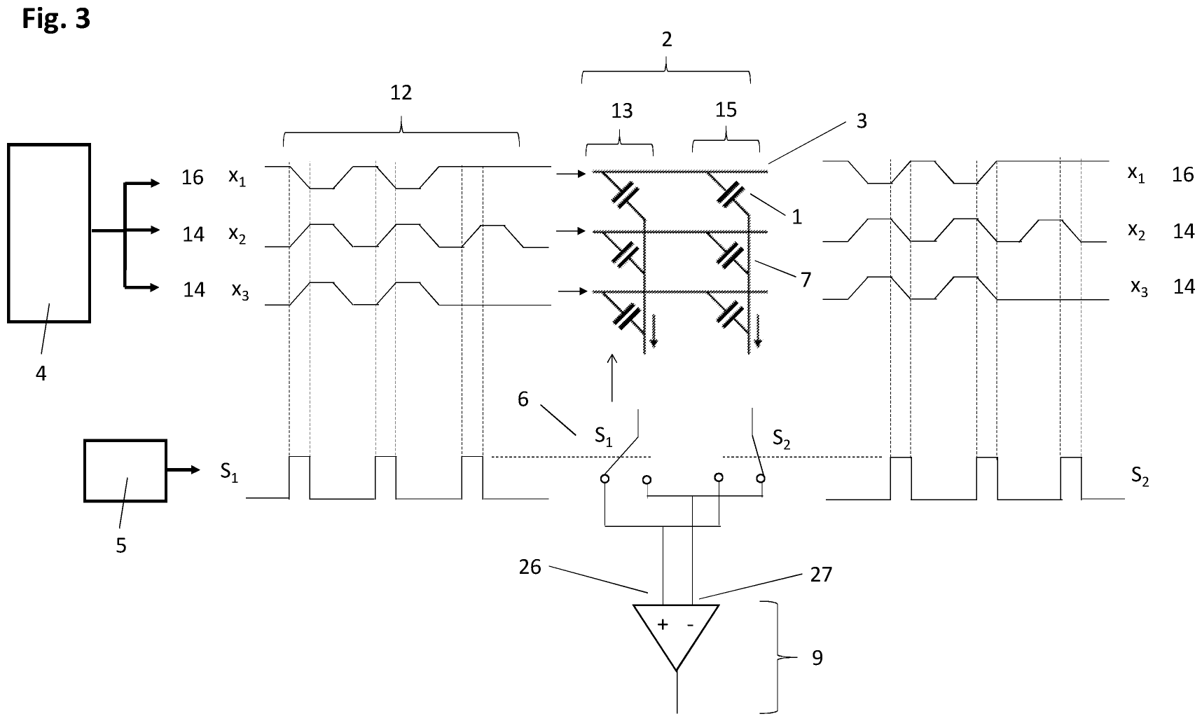

FIG. 3: shows a circuit design and alternating signal relationships for a capacitive matrix with a charge integration amplifier having an inverting input and a non-inverting input

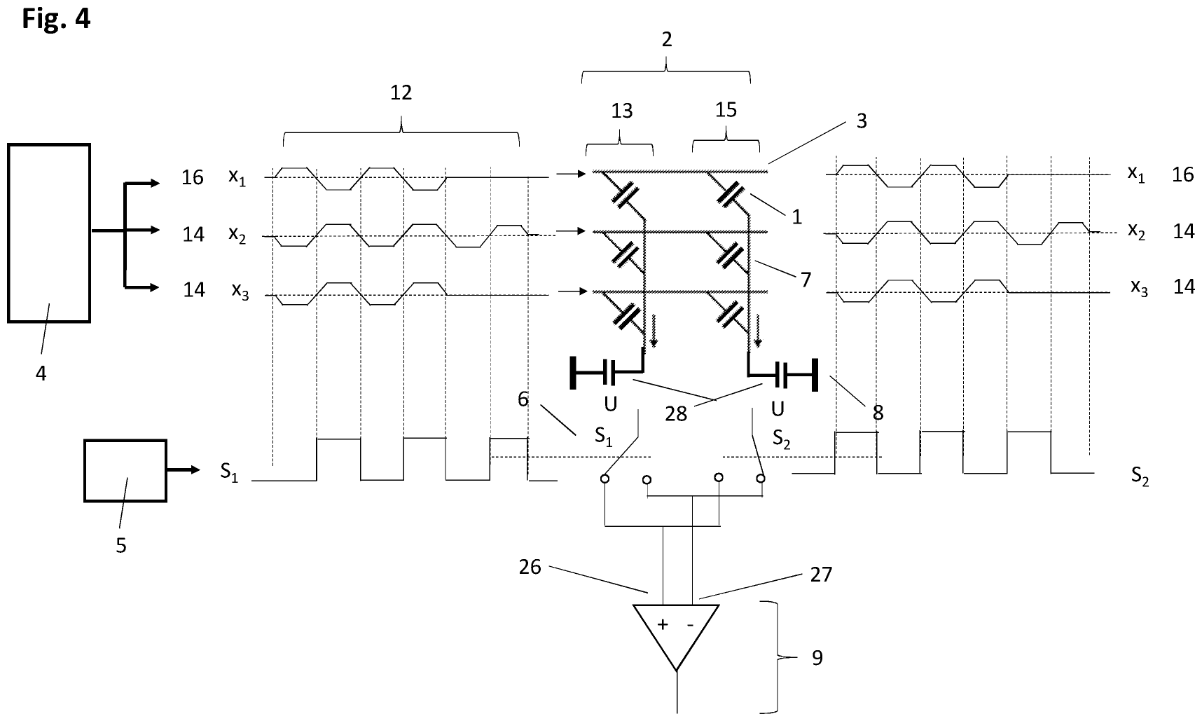

FIG. 4: shows a circuit design and alternating signal relationships for a capacitive matrix with an additional fixed capacitance on each bit line

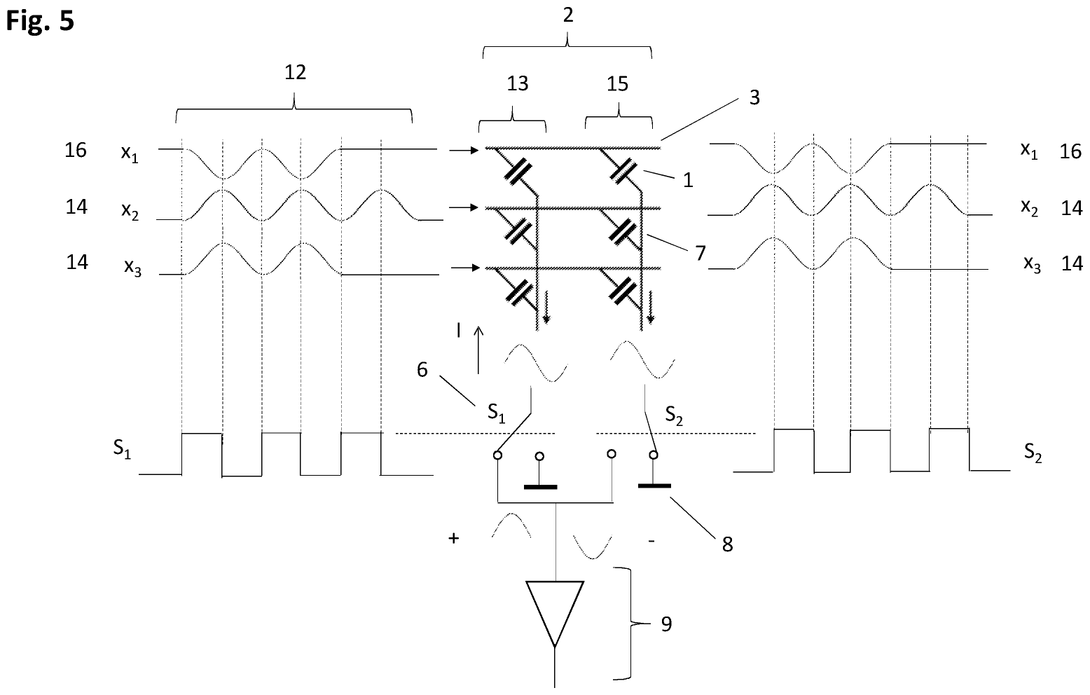

FIG. 5: shows harmonic alternating signals for a capacitive matrix

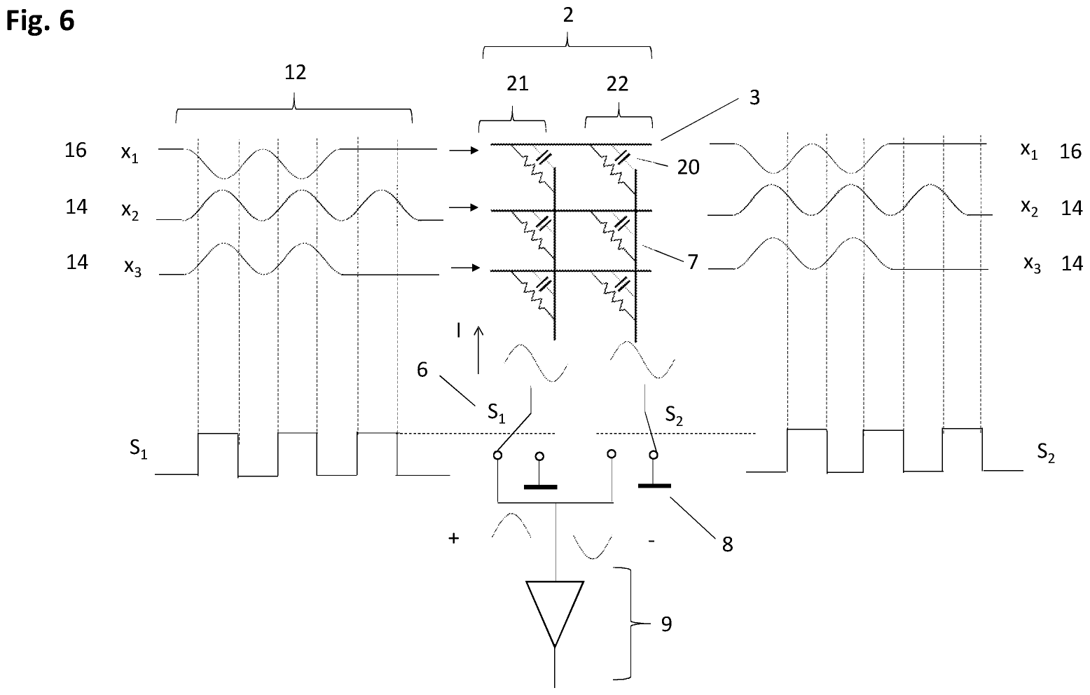

FIG. 6: shows harmonic alternating signals for a mixed capacitive-resistive matrix

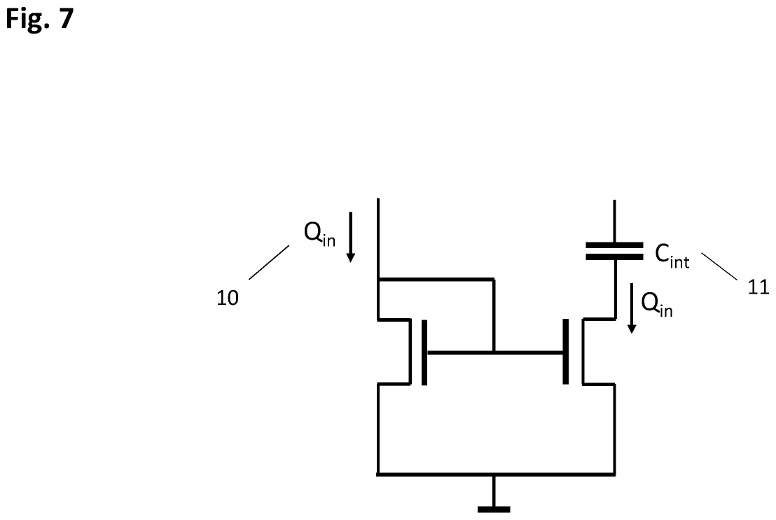

FIG. 7: shows a charge integration amplifier with a current mirror

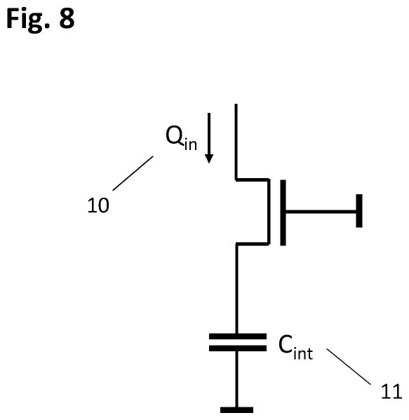

FIG. 8: shows a charge integration amplifier with a gate circuit

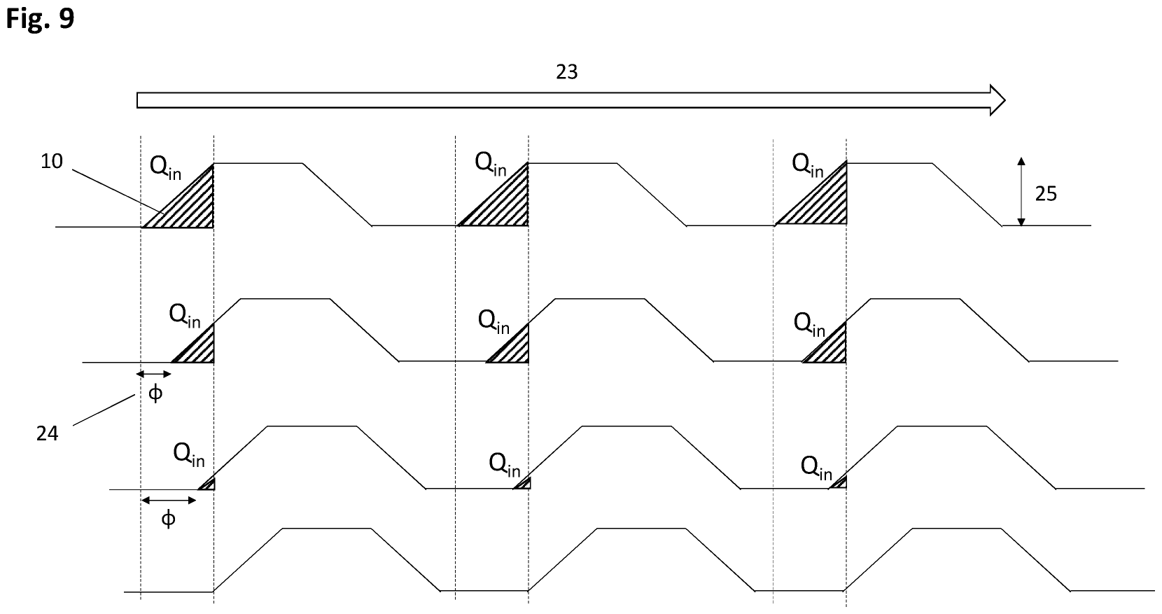

FIG. 9: shows the influence of the phase shift on the integrated charge for an arbitrary alternating signal, and the variation of the number of periods and the amplitude

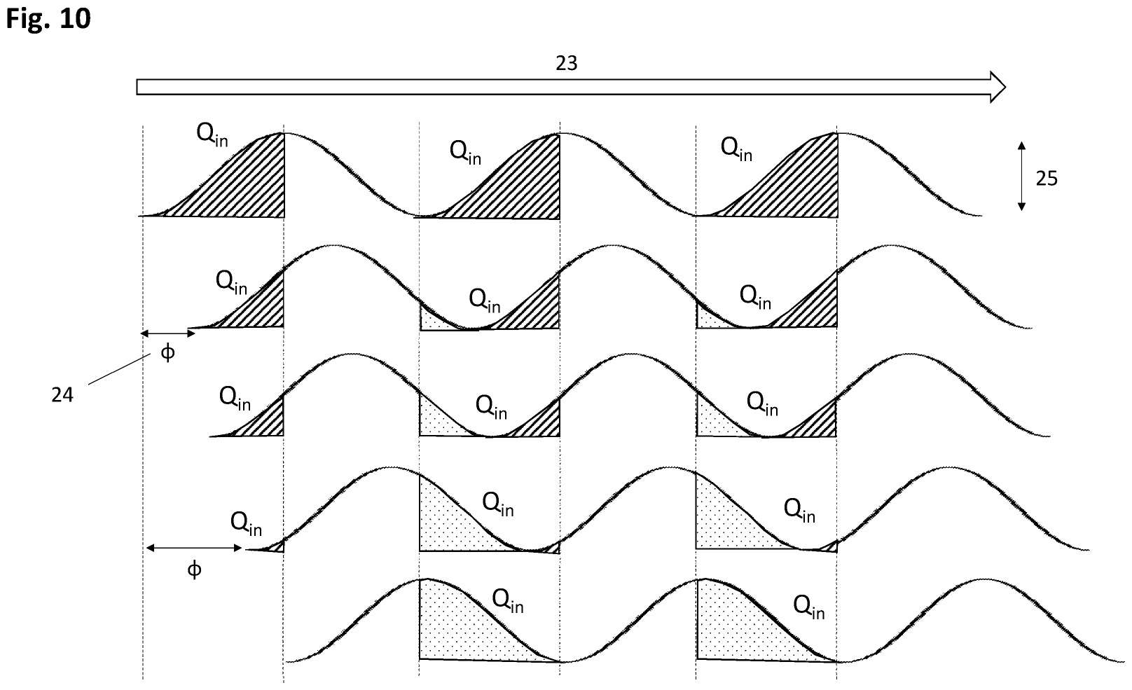

FIG. 10: shows the influence of the phase shift on the integrated charge for a harmonic alternating signal, and the variation of the number of periods and the amplitude

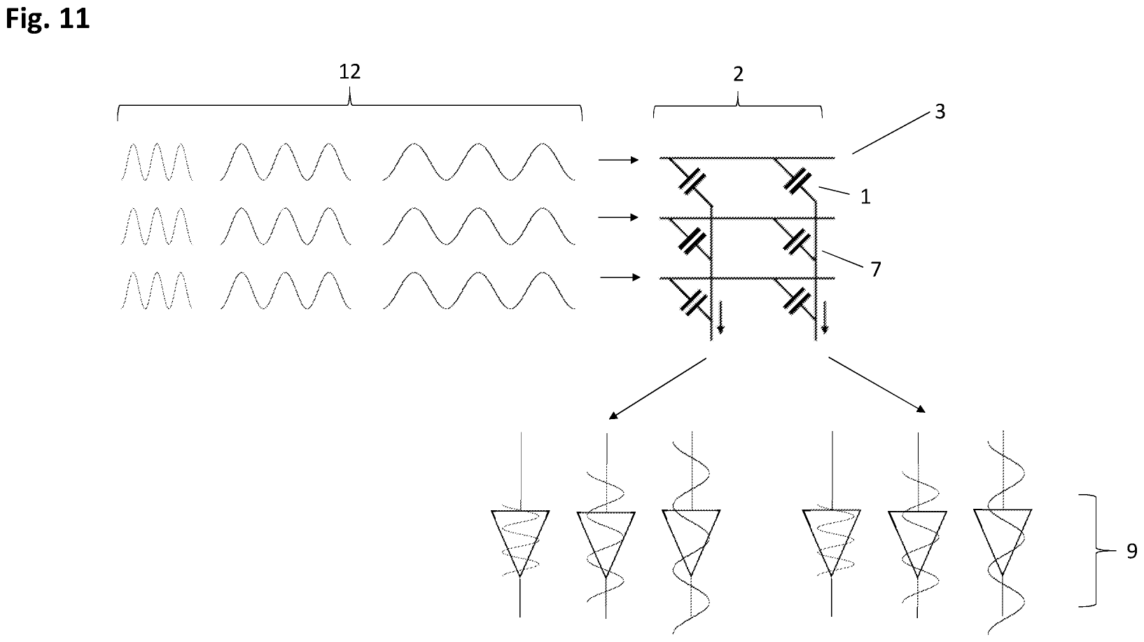

FIG. 11: shows the application of a plurality of alternating signals in different frequency bands.

As illustrated in FIG. 1, a plurality of AC voltages (12) which differ in terms of the phase, amplitude or the number of periods are applied to the word lines (3). Since there is a capacitive matrix arrangement (2) in this case, the capacitive synaptic components (2) react to rising or falling edges and the clock generator (5) outputs a positive signal when there is a rising edge in the positively defined AC voltage signal (14). In this case, the changeover switch (S1) will connect the positively defined synaptic components (13) to the charge integration amplifier (9). The changeover switch (S2) connects the negatively defined synaptic components (15) to ground (8) in this position, that is to say S1 and S2 switch in an opposite manner. The negatively defined synaptic components (15) are connected to the charge integration amplifier (9) when there is a falling edge in the positively defined AC voltage signal (14). Overall, this results in a positively defined AC voltage signal causing a charge in the charge integration amplifier (9) for the positively defined synaptic components (13) and causing a discharge for the negatively defined synaptic components (15). For negatively defined AC voltage signals (16), the rising and falling edges are swapped in time, that is to say the positively defined synaptic components (13) cause a discharge, while the negatively defined synaptic components (15) cause a charge. This achieves a four-quadrant multiplication. The AC voltage signals are realized by means of oscillators (4). FIG. 1 likewise illustrates, by way of example, a smaller number of periods for the negatively defined AC voltage signal (16) than for the positively defined AC voltage signals (14). This is a possible way of setting the magnitude of the input signal with respect to the word line (3) since, in this example, the positively defined synaptic components (13) are charged more frequently than discharged.

FIG. 2 explains the case for resistive synaptic components (19). In this case, the components cause a charge and a discharge for AC voltage signals (12) in the positive and negative value range. Accordingly, the clock generator (5) reacts to the positive and negative value range of the AC voltage signal, rather than to the rising or falling edge, in the resistive case. Otherwise, the method of operation of the changeover switches (6) is identical to FIG. 1.

FIG. 3 shows the case for a charge integration amplifier (9) having a non-inverting input (26) and an inverting input (27). In this case, switching back and forth between the two inputs is carried out, as a result of which both phases are used and the effective gain is doubled.

FIG. 4 illustrates the case in which the capacitive matrix with a fixed capacitance (28) on the bit line (7) is connected to ground. This may be the parasitic bit line capacitance, for example. As a result, the voltage drop across this capacitance is switched to the charge integration amplifier (9), with the result that the clock generator (5) reacts to the positive and negative value range of the AC voltage signal (12).

FIG. 5 illustrates the same principle for a harmonic signal.

FIG. 6 shows the scheme for a mixed capacitive-resistive matrix. In this case, the clock generator (5) reacts with any phase to the AC voltage signal (12). The capacitive-resistive components (20) result in a phase shift of the charge and discharge that can be set in any desired manner. Therefore, the weight value cannot only be set by means of the absolute impedance value, but also by means of the complex and real parts of the impedance.

FIG. 7 shows a charge integration amplifier (9) having a current mirror topology. The current mirror has a low input impedance and mirrors the charge (10) to an integration capacitor (11).

FIG. 8 shows a charge integration amplifier (9) having a gate circuit which likewise has a low input impedance.

FIG. 9 shows the possibilities for representing an input value for the AC voltage signal (12). One possibility is to change the amplitude (25); furthermore, the number of periods can be changed, as already explained. In both cases, more or fewer charges are accumulated on the charge integration amplifier (9) over a period. Furthermore, the phase (24) can also be changed since the AC voltage signal (12) is always integrated only over certain periods of time, as illustrated. In the uppermost case, the complete rising edge is integrated. For the AC voltage signals (12) underneath, the integration period (represented as a dashed line), which is covered by the rising edge, becomes shorter and shorter. As a result, the accumulated charge likewise becomes lower.

FIG. 10 shows the same relationship as in FIG. 7 but only with a harmonic signal, wherein the integration period can now comprise the rising and falling edges. The lowermost curve represents a phase shift of 180° and comprises the falling edge, whereas the uppermost curve comprises the rising edge. The middle curve comprises the falling edge and the rising edge in equal parts, with the result that the integration value is zero in this case.

FIG. 11 shows the application of a plurality of AC voltage signals (12) at once to the word lines (3) with a different frequency. There is a separate charge integration amplifier (9) for each frequency band, as a result of which a plurality of vectors can be multiplied by the same weights. This case is particularly relevant in convolutional neural networks.

### LIST OF REFERENCE SIGNS

1 Capacitive synaptic component
2 Matrix arrangement
3 Word lines
4 Oscillator
5 Clock generator
6 Changeover switch
7 Bit lines
8 Ground
9 Charge integration amplifier
10 Charge
11 Integration capacitor
12 AC voltage signal
13 Positively defined capacitive synaptic component
14 Positively defined AC voltage signal
15 Negatively defined capacitive synaptic component
16 Negatively defined AC voltage signal
17 Positively defined resistive synaptic component
18 Negatively defined resistive synaptic component
19 Resistive synaptic component
20 Mixed capacitive-resistive synaptic component
21 Positively defined capacitive-resistive synaptic component
22 Negatively defined capacitive-resistive synaptic component
23 Number of periods
24 Phase shift
25 Amplitude change
26 Non-inverting input
27 Inverting input
28 Fixed capacitance

1. An arrangement for performing a vector-matrix multiplication by means of synaptic components, comprising a matrix arrangement of capacitive synaptic components or resistive synaptic components or mixed capacitive-resistive synaptic components in a differential arrangement, with periodic charging and discharging, and a clock generator, wherein:
the clock generator is designed to alternately connect the bit lines to a charge integration amplifier or ground via a changeover switch or is designed to alternately connect the bit lines to a non-inverting input and an inverting input of the charge integration amplifier via a changeover switch,
the word lines are electrically connected to one or more oscillators,
the clock generator is designed to react to a rising or falling edge of the voltage of the oscillator or to the positive and negative value range of the voltage of the oscillator.

2. The arrangement as claimed in claim 1, wherein, in the case of capacitive synaptic components, in particular positively defined capacitances and negatively defined capacitances, the clock generator is designed to react to a rising or falling edge of the voltage of the oscillator.

3. The arrangement as claimed in claim 1, wherein, in the case of capacitive synaptic components, in particular positively defined capacitances and negatively defined capacitances, the bit line is connected to ground via a fixed capacitance and the clock generator is designed to react to the positive and negative value range of the voltage of the oscillator.

4. The arrangement as claimed in claim 1, wherein, in the case of resistive synaptic components, in particular positively defined resistances and negatively defined resistances, the clock generator is designed to react to the positive and negative value range of the voltage of the oscillator.

5. The arrangement as claimed in claim 1, wherein the charge integration amplifier is constructed from a current mirror mirroring the charge to be measured to the integration capacitance.

6. The arrangement as claimed in claim 1, wherein, in the charge integration amplifier, the integration capacitance is connected to the changeover switch via a gate circuit.

7. The arrangement as claimed in claim 1, wherein, in the charge integration amplifier, the integration capacitance is directly connected to the changeover switch.

8. The arrangement as claimed in claim 1, wherein, in the charge integration amplifier, the integration capacitance appears in an enlarged form at the input of the charge integration amplifier via the Miller effect.

9. The arrangement as claimed in claim 1, wherein the oscillators have an energy store which can recover the charges stored in the capacitive synaptic components for further use.

10. The arrangement as claimed in claim 9, wherein the energy store is implemented by means of an inductance.

11. A method using the arrangement as claimed in claim 2, wherein periodic AC voltages are applied to the word lines, and wherein:
the AC voltages have a fixed phase relationship,
in the case of an alternating connection between ground and the input of the charge integration amplifier, the bit line of the positively provided capacitances is connected to the input of a charge integration amplifier when there is a positive gradient in the positively defined AC voltage signal of the word line, and is otherwise connected to ground,
the bit line of the capacitances provided as negative is connected to the input of the charge integration amplifier when there is a negative gradient in the positively defined AC voltage signal of the word line, and is otherwise connected to ground,
in the case of an alternating connection between the inverting input and the non-inverting input of the charge integration amplifier
the positively provided capacitances are connected to the non-inverting input of a charge integration amplifier when there is a positive gradient in the positively defined AC voltage signal of the word line, and are otherwise connected to the inverting input, and
the negatively provided capacitances are connected to the non-inverting input of a charge integration amplifier when there is a negative gradient in the positively defined AC voltage signal of the word line, and are otherwise connected to the inverting input, and
wherein, in the case of a negatively defined AC voltage signal, the positive and negative gradients are swapped in time on the word line.

12. A method using the arrangement as claimed in claim 3, wherein periodic AC voltages are applied to the word lines, and wherein:
the AC voltages have a fixed phase relationship,
in the case of an alternating connection between ground and the input of the charge integration amplifier
the positively provided capacitances or resistances are connected to the input of a charge integration amplifier when there is a positive value range in the positively defined AC voltage signal of the word line, and are otherwise connected to ground,
the bit line of the capacitances or resistances provided as negative is connected to the input of the charge integration amplifier when there is a negative value range in the positively defined AC voltage signal of the word line, and is otherwise connected to ground,
in the case of an alternating connection between the inverting input and the non-inverting input of the charge integration amplifier
the positively provided capacitances or resistances are connected to the non-inverting input of a charge integration amplifier when there is a positive value range in the positively defined AC voltage signal of the word line, and are otherwise connected to the inverting input, and
the negatively provided capacitances or resistances are connected to the non-inverting input of a charge integration amplifier when there is a negative value range in the positively defined AC voltage signal of the word line, and are otherwise connected to the inverting input, and
wherein, in the case of a negatively defined AC voltage signal, the positive and negative value ranges are swapped in time on the word line.

13. A method using the arrangement as claimed in claim 1, wherein periodic AC voltages are applied to the word lines, and wherein:
in the case of mixed capacitive-resistive synaptic components and in the case of an alternating connection between ground and the input of the charge integration amplifier
the bit line of the capacitive-resistive components provided as positive is connected to the input of the charge integration amplifier at any time for a period of half a period duration of the positively defined AC voltage signal and is connected to ground for a subsequent period of half a period duration of the positively defined AC voltage signal,
the periods for a connection between the bit line and the charge integration amplifier and between the bit line and ground are swapped in the case of the negatively provided capacitive-resistive components,
in the case of an alternating connection between the inverting input and the non-inverting input of the charge integration amplifier
the bit line of the capacitive-resistive components provided as positive is connected to the non-inverting input of the charge integration amplifier at any time for a period of half a period duration of the positively defined AC voltage signal and is connected to the inverting input for a subsequent period of half a period duration of the positively defined AC voltage signal,
the periods for a connection between the bit line and the non-inverting input of the charge integration amplifier and between the bit line and the inverting input are swapped in the case of the negatively provided capacitive-resistive components, and
wherein, in the case of a negatively defined AC voltage signal on the word line, the two periods are likewise swapped.

14. The method as claimed in one of claim 11, wherein:
the AC voltage signals (12) are harmonic, and
positive and negative AC voltage signals (14, 16) are phase-shifted through 180°.

15. The method as claimed in one of claim 11, wherein:
the input variable can be represented either as a variable number of periods,
or as a phase shift,
or as an amplitude change,
or as a frequency change of the AC voltage signal,
or as a changed DC component of the AC voltage signal,
or as a combination of the changes mentioned above.

16. The method as claimed in claim 13, wherein the weights in a mixed capacitive-resistive matrix can also be set by means of the complex and real parts for a constant impedance and cause a phase shift of the AC voltage signal.

17. The method as claimed in one of claim 11, wherein a plurality of AC voltage signals are applied to the word lines in a parallel manner and differ in terms of the frequency, and a plurality of charge integration amplifiers which are each responsible for the individual frequency bands are respectively situated on the bit lines.

18. The method as claimed in claim 17, wherein the charge integration amplifier selects the appropriate frequency at the input using a bandpass filter and is constructed, for example, in the form of a lock-in amplifier.

19. The method as claimed in one of claim 11, wherein the frequency of the applied AC voltage signal is minimized in the case of capacitive synaptic components to such an extent that resistive losses in the supply lines of the matrix arrangement and in the capacitive synaptic component itself are smaller by at least one order of magnitude than the capacitive energy supply.
